(19) United States
(12) Patent Application Publication
(10) Pub. No.: US 2026/0040729 A1
(43) Pub. Date: Feb. 5, 2026

(54) METHOD FOR PROCESSING AN OPTOELECTRONIC DEVICE AND OPTOELECTRONIC DEVICE

(71) Applicant: ams-OSRAM International GmbH, Regensburg (DE)

(72) Inventors: Marta Rio Calvo, Regensburg (DE); Martin Hetzl, Painten (DE); Adrian Avramescu, Regensburg (DE)

(21) Appl. No.: 19/099,394

(22) PCT Filed: Aug. 2, 2023
(86) PCT No.: PCT/EP2023/071477

§ 371 Date: Jan. 28, 2025

(30) Foreign Application Priority Data
Aug. 4, 2022 (DE) 102022119573.2

(51) Int. Cl. H10H 20/01; H10H 20/812; H10H 20/824

(52) U.S. Cl. CPC H10H 20/0133; H10H 20/812; H10H 20/824

(57) ABSTRACT

A method for processing an optoelectronic device includes providing a growth substrate having one of a [111], [110] or [100] surface with a (GaₓAl₁₋ₓ)_{y}In_{1-y}P buffer layer located on the growth substrate having a parameter x between 0.2 and 0.8, inclusive, and a parameter y between 0.3 and 0.7, inclusive, and re-growing a doped (GaₓAl₁₋ₓ)_{y}In_{1-y}P layer with a parameter x between 0.4 and 0.6, inclusive, and a parameter y between 0.3 and 0.7, inclusive, on exposed surfaces of an AlInP layer deposited on the buffer layer, the exposed surfaces surrounded by a structured hard mask comprising an amorphous material on non-exposed surfaces of the AlInP layer, wherein edges of the hard mask adjacent to at least one exposed portion of the of a surface of the AlInP layer extend along the [111] B lateral surfaces when the substrate has a [111] surface, or extend along the [110] lateral surfaces when the substrate has a [100] surface, or extend along the [100] lateral surfaces when the substrate has a [110] surface.

### CROSS-REFERENCE TO RELATED APPLICATIONS

This patent application is a national phase filing under section 371 of PCT/EP2023/071477, filed Aug. 2, 2023, which claims the priority of German patent application no. 10 2022 119 573.2, filed Aug. 4, 2022, each of which is incorporated herein by reference in its entirety.

### TECHNICAL FIELD

The present invention concerns a method for processing an optoelectronic device and an optoelectronic device.

### BACKGROUND

Light emitting diodes become increasingly small to comply with recent requirement and have recently reached sizes of less than 10 μm in size. Such light emitting diodes also referred to as μLEDs also suffer from various challenged due to the small size. Particularly, InGaAlP-based μLEDs are affected from a decreasing performance with smaller size.

The reason for the efficiency drop is caused by non-radiative recombination of injected charge carriers. Those occur mainly along the edges of the active region due to respective dangling bonds, crystal defects and other effects. InGaAlP material system also has a relatively large charge carrier diffusion length further increasing the issue. Fermi level pinning at the semiconductor surface becomes more prominent with increasing surface-to-volume-ratio of a μLED pixel, i.e., smaller size.

Several approaches have already been developed in order to increase μLED performance that is to reduce the non-radiative recombination at the layer facets of an active region. One possibility is passivation of the layer facets at the edges, for example by various dielectrics. However, it has been found that such solution does not significantly improve the performance.

Another way is the so-called impurity-induced intermixing of the active layer facets. With this method, the active layer region, most often a Quantum-Well, QW region is locally intermixed with a higher bandgap barrier material, leading to a net increase of the local bandgap. Usually, one can use a Zn doping for this purpose that causes an increase of the bandgap. The increase leads to an electric barrier potential, preventing charge carriers to diffuse from the center of the μLED to the facets and the surface. However, this is limited for device sizes larger than 10 to 20 micrometers, as the intermixing resolution would be insufficient for devices in the range of the above-mentioned sizes of 10 μm or less.

Yet another approach to improve the performance is based on so-called epitaxial regrowth. This process requires to locally etch the epitaxial layers including the active layer and the QWs away where the later pixel facets will be formed. The etching process is most often realized ex-situ by dry or wet etching, or in-situ by Cl-containing vapor within the epi reactor. Then, a material with a larger bandgap material is conducted over the whole wafer in a second epitaxial step, leading to an overgrowth of the non-etched islands as well as the etched regions. Similar to the intermixing approach, charge carriers are blocked by high energy barriers to prevent diffusion to the facet surface.

However, especially the etching process involves problems due to different layer compositions of the LED showing different etching behavior, leading to different etch slopes and kinks along the sensitive side facet of the etched pixel. During regrowth, this typically leads to crystal defects and, thus, potential origins for performance drops.

### SUMMARY

Embodiments provide a bottom-up regrowth process, referred to as selective area growth, SAG, to process optoelectronic devices avoiding an etching process that removes material from the active layer thereby preventing sidewall damages and contamination of the regrowth surface. The approach is particularly useful for InGaAlP-based (GaAsP-based) μLEDs, in which the diffusion length may be in the range of the μLED size.

Consequently, the inventors propose a method for processing an optoelectronic device, in which a growth substrate having one of a [111], [110] or [100] surface, in particular a GaAs substrate having one of a [111], [110] or [100] surface is provided. A (GaₓAl₁₋ₓ)_{y}In_{1-y}P buffer layer is deposited on the growth substrate, whereas the parameter x between 0.2 and 0.8 and more particularly between 0.3 and 0.7 and more particularly between 0.4 and 0.6 and parameter y between 0.3 and 0.7 and more particularly between 0.4 and 0.6 is deposited on the growth substrate.

A doped (GaₓAl₁₋ₓ)_{y}In_{1-y}P layer with parameter x between 0.4 and 0.6 and in particular 0.5 and parameter y between 0.3 and 0.7 and more particularly between 0.4 and 0.6 is now regrown on exposed surfaces of an AlInP layer deposited on the buffer layer. Said exposed surface are surrounded by a structured hard mask comprising an amorphous material on the non-exposed surface of the AlInP layer, wherein edges of the hard mask adjacent to the at least one exposed portion of the of the surface of the AlInP layer extend along the [111] B lateral surfaces if the substrate has a [111] surface, or extend along the [110] lateral surfaces if the substrate has a [100] surface, or extend along the [100] lateral surfaces if the substrate has a surface. An active layer structure is regrown on the doped (GaₓAl₁₋ₓ)_{y}In_{1-y}P layer.

In particular in case of the substrate having a [111] surface, the re-grow step is performed under growth conditions that are optimized to block lateral growth along planes other than [111]. This is achieved by certain material ration of the respective precursors for the V/III materials and/or the temperature.

Furthermore, a doped or intrinsic (GaₓAl₁₋ₓ)_{y}In_{1-y}P layer is re-grown along a top surface and the sidewalls of the active layer down to the hard mask. The (GaₓAl₁₋ₓ)_{y}In_{1-y}P layer comprises a bandgap that is larger than a bandgap of the active layer on the sidewalls. In this regard it is noted that parameter x can be set to 0 such that an AlInP layer is regrown on the active layer and its sidewalls. As in the previous steps, the growth parameters (material composition, temperature etc) for wide bandgap material are adjusted such as to enhance lateral overgrowth. As a result of the last re-growth process, the active layer is fully encapsulated by wide bandgap material without any secondary treatment of the active layer itself. The crystallographic passivation/encapsulation of the active layer region will block charge carrier from diffusing towards the semiconductor surface resulting in non-radiative recombination. A thickness of this layer needs to be adjusted to satisfy current spreading and passivation of active layer at the same time.

The proposed approach contains less risk of contamination because of multiple process steps and thus results in a higher crystal quality and a reduction of dislocations compared to regrowth approach on different lattice planes. The [111] surface is of particular use, as this surface promotes a selective growth in certain direction which is supported by the respective growth conditions for each layer to prevent deposition on the amorphous hard mask material.

Finally, an unstructured conductive material is deposited on the whole structure and the device mesa structured to provide the optoelectronic device. It can then be separated or re-bonded to enable contacting the other side.

In some aspects and in particular in case of the substrate having a [111] surface, the edges of the hard mask adjacent to the at least one exposed portion of the surface of the AlInP layer extend along the [111] lateral surfaces. Alternatively or additionally edges of the hard mask adjacent to the at least one exposed portion of the of the surface of the AlInP layer form a triangle or a hexagonal structure in top view with its side along a [111] lateral surface. The design of the hard mask with its edges along the [111] surface therefore facilitate and support the selective growth. A rectangle or quadrature recess is not overly beneficial as it comprises edges not along the [111] surfaces, thereby increasing the risk of dislocations during the growth process. However a rectangle or quadrature recess oriented towards the [110] or [100] direction may be beneficial in case of the substrate having a [110] or [100] surface. In particular the edges of the hard mask adjacent to the at least one exposed portion of the surface of the AlInP layer extend along the [110] lateral surfaces in case of the substrate having a [100] surface, or the edges of the hard mask adjacent to the at least one exposed portion of the surface of the AlInP layer extend along the [100] lateral surfaces in case of the substrate having a [110] surface.

The re-growth of the doped (GaₓAl₁₋ₓ)_{y}In_{1-y}P layer is done by various different way. In some aspects, an AlInP layer is deposited on the buffer layer. The AlInP layer can be doped or intrinsic. Also doping profiles for the AlInP layer are possible. Then, the structured hard mask is created on the surface of the AlInP layer. The structured hard mask is deposited in some instances and a recess is subsequently etched in the respective amorphous material. The recess exposes a portion of the surface of the underlying AlInP layer.

In an alternative approach, a hard mask material is directly applied on the buffer layer and then etched to subsequently form a recess. As in the previous approach, the recess exposes a portion of underlying surface material, that is a portion of the buffer layer surface. By selecting proper growth conditions, an AlInP layer, and particular an intrinsic AlInP layer is grown on the exposed portions of the buffer layer. The doped (GaₓAl₁₋ₓ)_{y}In_{1-y}P layer is subsequently selectively deposited on the top surface of the AlInP layer, particularly above the exposed portions.

In yet another alternative approach an AlInP layer in particular intrinsic AlInP layer is deposited on the buffer layer. A structured photoresist is then applied on the AlInP layer and subsequently, the AlInP layer is selectively etched to form a protrusion. The protrusion will subsequently act as a selective growth surface for subsequent layers. In some instances, the step of etching the AlInP layer forms inclined sidewalls with an increasing area towards the buffer layer. Consequently the protrusion may comprise an inclined surface i.e. with an angle in the range of 0° (substantially perpendicular protrusion) to about 50°.

In some further steps, the amorphous material of the hard mask is applied on top surface portions of the AlInP layer surrounding the protrusion. After removal of a photoresist (if any), the doped (GaₓAl₁₋ₓ)_{y}In_{1-y}P layer is selectively deposited on the top surface of the protrusion.

Due to respective growth conditions, the doped (GaₓAl₁₋ₓ)_{y}In_{1-y}P material is deposited mainly inside the recess (where applicable) and on the on the exposed surface. As the [111] surface is maintained during the growth of the buffer layer, a selective growth of the doped (GaₓAl₁₋ₓ)_{y}In_{1-y}P material and subsequent layers are facilitated. Due to the growth conditions, the (GaₓAl₁₋ₓ)_{y}In_{1-y}P material or the AlInP layer does not grow on the amorphous hard mask layer material but mainly on the exposed surface.

In some aspects and depending on the selected material and the chosen re-growth process, a top surface of the deposited doped (GaₓAl₁₋ₓ)_{y}In_{1-y}P layer may exceed a top surface of the hard mask. Alternatively, depending on the chosen growth process, a top surface of the AlInP layer exceeds a top surface of the hard mask.

The temperature range for the selective growth of the doped (GaₓAl₁₋ₓ)_{y}In_{1-y}P layer is above 500° C. and in particular in the range of 650° C. to 800° C. and more particular between 670° C. and 750° C. and more particular between 700° C. to 730° C. in some other instances, the buffer layer is n-doped and the AlInP layer is n-doped or substantially intrinsic.

The amorphous material comprises a material that is suitable for the high temperature and does not decompose. For example SiO₂ SiN and Al₂O₃ are suitable materials for this purpose.

The active layer structure may comprise a single quantum well, but also a multi-quantum well structure. In some instances, re-growing of an active layer structure includes depositing a plurality of alternating layers of (GaₓAl₁₋ₓ)_{y}In_{1-y}P layers with different Al content. In addition, the In content may vary as well to reduce strains on the structure. Different doping in the range of 5e15 1/cm³ to 1e17 1/cm³ can be used when needed.

During the regrowth process, a portion of the re-grown doped (GaₓAl₁₋ₓ)_{y}In_{1-y}P layer can exceed partially onto the top surface of the hard mask. This portion is small and in the range of a few 10 nm up to about 200 nm surrounding the now filled recess. The top surface of hard mask is recessed with respect to the protruding selectively grown layer structure.

Likewise, a thickness of the re-grown doped or intrinsic (GaₓAl₁₋ₓ)_{y}In_{1-y}P on the sidewalls of the active layer is in the range between 10 nm and 200 nm and in particularly between 10 nm and 100 nm. The thickness on the top surface us usually larger. The thickness can be adjusted to satisfy current spreading in this layer and passivation of active layer at the same time. In some instances, the (GaₓAl₁₋ₓ)_{y}In_{1-y}P layer may comprise a doping profile to enhance current injection into the active layer.

For this purpose it may be suitable in some instances to deposit a p-doped contact layer on the top surface of the re-grown doped or intrinsic (GaₓAl₁₋ₓ)_{y}In_{1-y}P layer, particular comprising GaP or GaAs. The deposition may either be achieved by a selective growth on the 111 facets (that is the top surface) of the (GaₓAl₁₋ₓ)_{y}In_{1-y}P layer. Alternatively, an isotropic overgrowth of the p-doped contact layer can be performed also on the side facet if the design is properly adjusted to avoid charge carriers leaking into the pn-junction from the side. The unstructured conductive material comprises one of ITO, Ag, Ti, TiN, and Au.

Another aspect concerns an optoelectronic device that comprises a structured semiconductor layer stack arranged between a first contact area on a light emission surface and a second contact area on a surface opposite the light emission surface. The semiconductor layer stack further comprise a hard mask layer made of an amorphous material and having a recess. A doped (GaₓAl₁₋ₓ)_{y}In_{1-y}P layer with parameter x between 0.4 and 0.6 and in particular 0.5 and parameter y between 0.3 and 0.7 and more particularly between 0.4 and 0.6 is located above or within the recess of the hard mask layer. Its top surface elevates above a surface of the hard mask.

In accordance with the proposed principle, an active layer is selectively deposited on said top surface of the (GaₓAl₁₋ₓ)_{y}In_{1-y}P layer. The active layer comprises a quantum well or multi-quantum well structure based on InGaAlP material with different Al contents between well layer and adjacent barrier layers of the quantum well or multi-quantum well structure. A doped or an intrinsic (GaₓAl₁₋ₓ)_{y}In_{1-y}P layer is deposited on a top surface and sidewalls of the active layer exceeding down to the hard mask layer.

The optoelectronic device therefore contains the hard mask layer, that was previously used for a selective growth process of the active layer and the (GaₓAl₁₋ₓ)_{y}In_{1-y}P layer located above the recess. It should be noted in this regard that particularly the (GaₓAl₁₋ₓ)_{y}In_{1-y}P layer does not significantly exceed on the top surface of the hard mask layer. In some embodiments there is material of the (GaₓAl₁₋ₓ)_{y}In_{1-y}P layer arranged above the hard mask layer surrounding the recess, but the overall area of the amorphous material covered by the (GaₓAl₁₋ₓ)_{y}In_{1-y}P layer is very small compared to the area of the recess. In some instances the so called “overlap” is only a few 10 nm to about 150 nm.

The hard mask enables a selective growth and re-growth of layers without introducing defects and dislocations at the edges of the active layer. This approach is in particular in case of the substrate having a [100] surface beneficial, in particular when edges of the hard mask layer adjacent to the recess extend along [111] lateral surfaces, on which the hard mask layer is arranged as it is the case in some instances.

In some other instances the hard mask is arranged on an underlying layer thereby exposing some portions of said layer with the recess. The edges of the hard mask adjacent to the at least one exposed portion of the surface of an underlying layer, in particular an AlInP layer form in top view a triangle or a hexagonal structure with its side along a [111] lateral surface, in particular in case of the substrate having a [100] surface.

Consequently, the structured semiconductor layer stack further comprises an AlInP layer in some instances. The material of the AlInP layer may in some embodiments at least partially fill the recess. Alternatively or additionally, the material of the AlInP forms the underlying layer, upon which the hard mask layer is arranged. It may also in some instances comprise at least partially inclined sidewalls adjacent to the amorphous material of the had mask layer. In such instances, material of the AlInP forms a protrusion exceeding from the surrounding hard mask material. on its top surface the (GaₓAl₁₋ₓ)_{y}In_{1-y}P layer is arranged upon.

In some embodiments, the optoelectronic device further comprises an unstructured conductive material, in particular a metal on the doped or intrinsic (GaₓAl₁₋ₓ)_{y}In_{1-y}P layer. The conductive material is also deposited on the surrounding material of the hard mask layer. This is a simple solution and does not degrade the device as the hard mask layer contains an insulating material, including but not limited to one of SiO₂, SiN and Al₂O₃. The latter can also be utilized as passivation layer on the mesa surfaces of the device. In some further embodiments the unstructured conductive material comprises one of ITO, Ag, Ti, TiN, and Au.

### BRIEF DESCRIPTION OF THE DRAWINGS

Further aspects and embodiments in accordance with the proposed principle will become apparent in relation to the various embodiments and examples described in detail in connection with the accompanying drawings.

FIGS. 1A to 1H illustrate steps of a method for processing an optoelectronic device in accordance with some aspects of the proposed principle;

FIG. 2 shows a variation of a processing step of a method for processing an optoelectronic device in accordance with some aspects of the proposed principle;

FIGS. 3A and 3B illustrate results of some processing steps of a method in accordance with the proposed principle;

FIGS. 4A to 4C illustrate further steps of another embodiment of a method for processing an optoelectronic device in accordance with some aspects of the proposed principle;

FIG. 5 shows a variant of an optoelectronic device in accordance with some aspects of the proposed principle; and

FIG. 6A to 6C illustrate variant of an opening in the hard mask or a protrusion of the underlying material in accordance with several aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual Figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the Figures. So it is possible to deduce such relations between the elements based on the Figures.

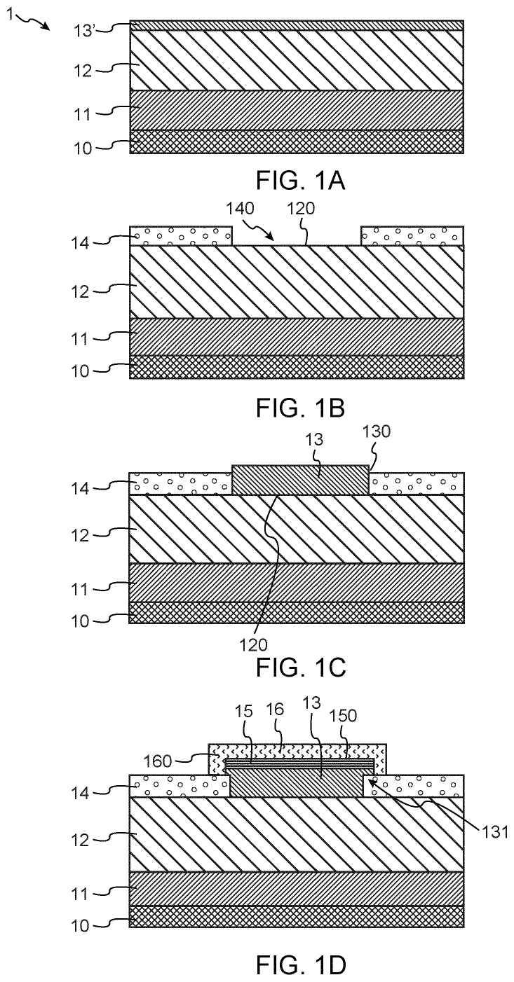

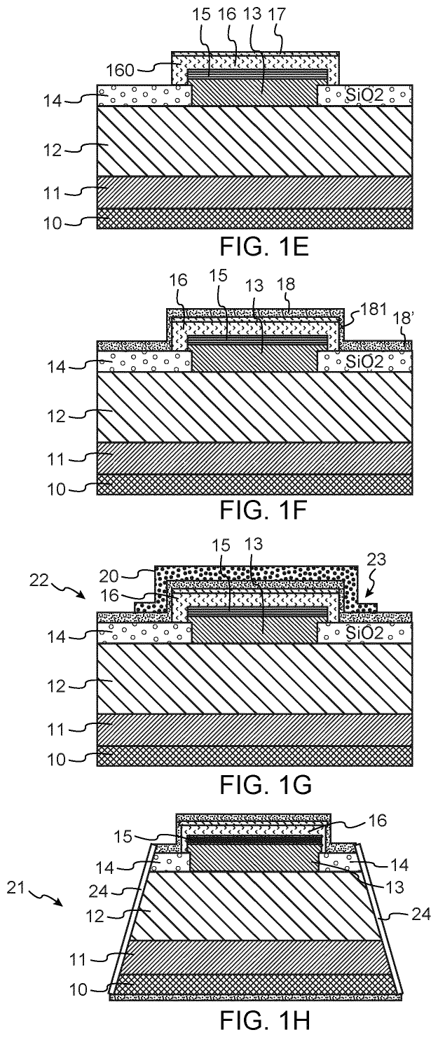

FIGS. 1A to 1H illustrate several steps of a method for processing an optoelectronic device in accordance with the proposed principle.

The proposed method is based on a bottom-up re-growth process also referred to as selective area growth or SAG to process optoelectronic devices having a very small edge size based on the InGaAlP material system. The proposed bottom-up regrowth process is an alternative to conventional re-growth processes, but avoids etching the sidewall of the active layer, thereby preventing damages and contamination to the active layer's surface. The proposed approach provides an easier fabrication and less risk of contamination due to the reduced number of process steps involved. As a result, a higher quality in crystal growth particularly around the active layer as well as the reduction of dislocations on the different lattice planes is achieved.

The exemplary shown process requires a {111}-oriented GaAs substrate as a growth substrate to promote a selective growth in the respective crystal directions. For the purpose of this application a {111}-oriented substrate (including all equivalent [111] planes) and [111] direction shall be used synonymous. It means that the orientation as well as the surface of the respective growth substrate facilitates and supports growth of the ternary InAlP material as well as the quaternary InGaAlP material smoothly and at least from an ideal crystallographic perspective only with monoatomic crystal step (in contrast to other direction which require a biatomic step).

The [111] oriented plane on the GaAs growth substrate 10 enables a deposition of further layers in a monoatomic step with suitable precursors. In such way that no or only a very few dislocations due to crystal step in the usual growth direction occurs and those do not usually continue through the buffer layer (that is they are overgrown easily). As such, the [111] oriented GaAs substrate 10 is utilized to reduce the dislocations in the further crystal growth.

As illustrated in FIG. 1A the growth substrate 10 with its [111] oriented surface plane is provided and an n-doped (Ga) AlInP layer is epitaxially deposited thereupon. In the present example, a (GaₓAl₁₋ₓ)_{y}In_{1-y}P buffer layer material 11 having parameter x between 0.2 and 0.8 and more particularly between 0.3 and 0.7 and more particularly between 0.4 and 0.6 and parameter y between 0.3 and 0.7 and more particularly between 0.4 and 0.6 is deposited on the growth substrate. As it can be seen from parameter x, this can also be zero, thereby creating a pure AlInP layer on the growth substrate.

In some instances, the n-doped layer 11 also acts as a current injection layer into the subsequent layers and the active layer of the respective optoelectronic device. Consequently, the n-doped buffer layer 11 may comprise a variation in parameters x and y, for example changing the In content to introduce a small variation of strain in order to change the bandgap in the active region later on thereby changing the colour of the emitted light. Furthermore, the doping level may be adjusted to reduce the resistance of the layer.

On top of buffer layer 11 an intrinsic, that is mainly undoped bottom layer 12 of InAlP material is deposited. It is possible to transform from the buffer layer 11 to layer 12 in a smooth way by reducing the Ga content during the epitaxial growth process. While in the present example, the AlInP layer 12 is substantially undoped, a n-type doping profile can be induced to improve the carrier injection and transport behaviour into the active region.

An optional layer 13′ made of GaAlInP can be applied in accordance with FIG. 1A, which can also act as a further growth material for subsequent processes. However, said layer 13′ can also be omitted to simplify the manufacturing process. The GaAlInP comprises a composition of (GaₓAl₁₋ₓ)_{y}In_{1-y}P with x between 0.3 and 0.7 and more particular between 0.4 and 0.6. Parameter y is between 0.4 and 0.6 for example.

Due to the [111]-oriented growth substrate 10, all subsequent layers 11 and 12 are overgrown in such way that the respective top surfaces are also oriented in the same direction.

Continuing with FIG. 1B, a hard mask layer 14 made of an amorphous dielectric material is deposited on the top of the [111]-oriented surface of layer 12 and subsequently structured as well as etched to provide a recess 140 therein. The resulting recess has a certain structure when viewed from top as outlined with regards to FIG. 6. Its edges mainly follow the 111 direction of the underlaying layer. In the present example the recess comprises a hexagonal shape when viewed form top. The etching step will expose portions of the [111]-oriented top surface 120 of layer 12. In this regard, the structuring of hard mask 14 follows the location and orientation of the μLEDs during processing of the optoelectronic devices particularly on wafer level. In other words, the recesses define the optoelectronic devices on a wafer level.

Following FIG. 1C in a subsequent step, the recess 140 is filled with a (GaₓAl₁₋ₓ)_{y}In_{1-y}P material with parameter x between 0 and 0.6 and in particular 0.5 forming layer 13. With X being 0 the material becomes InAlP. Said material follows a selective area growth process using certain growth conditions, which favour a selective deposition of the GaAlInP filler material within the recess but not on the top surface of the amorphous material for the respective hard mask 14. As a possible example, a re-growth condition for layer 13 includes a regrowth temperature in the range of 700° C. to 730° C.

As a result for such conditions, any material deposited on the top surface of the amorphous dielectric 14 will be resorb again and re-grow in the recess. The selective re-growth process in the [111] direction continues until the filler material of layer 13 slightly elevates above the top surface of the respective hard mask 14. The elevation 130, illustrated in FIG. 1C may lead to a small overall growth 131 as shown in FIG. 1D, on the top surface of the surrounding amorphous material of hard mask 14. However, such overlap may be in the range of a few 10 nm to approximately 100 nm, which is orders of magnitude smaller than the size of the recess. The overlap can be controlled slightly with varying the growth conditions during the growth period.

In a subsequent step illustrated in FIG. 1D, a plurality of different a quantum well barrier layers material as well as quantum well layer material is re-grown on the surface of GaAlInP layer 13 to form a multi-quantum well structure and active layer 15. Quantum well layer and quantum barrier layer both comprise an GaAlInP material. However, the respective barrier layers comprise an aluminum content which is slightly higher than the respective aluminum content in the quantum well material resulting in a higher bandgap. Each barrier layer as well as each quantum well layer comprise a thickness of a few nanometres. Due to the selected re-growth conditions, the material of the barrier layers as well as the quantum well layers are grown only along the already existing elevated portion of GaAlInP material of layer 13 along its [111]-direction. Due to the re-growth condition and the selected area growth, particularly the edges of the active layer 15 are substantially free from dislocations and further crystal defects.

After the re-growth of the multi-quantum well structure 15, an anisotropic lateral overgrowth of a wider bandgap material than the bandgap of the active region takes place. This step is also illustrated in FIG. 1D by material layer 16

Layer 16 comprises a p-doped (GaₓAl₁₋ₓ)_{y}In_{1-y}P layer with parameter x between 0.3 and 0.7 and more particular between 0.4 and 0.6. Parameter x can also be 0 which corresponds to InAlP, but may comprise values like 0.45, 0.5 and 0.55 or 0.6. Furthermore x may correspond to a varying concentration decreasing from a value like 0.7 or 0.5 to 0. Parameter y is between 0.3 and 0.7 and particularly between 0.4 and 0.6. The p-doped GaAlInP layer 16 also acts as a current injection layer to provide carrier injection into the active layer region 15. The p-doped GaAlInP layer 16 encapsulates the multi-quantum well region 15, covering not only the top surface of the active layer 15, but also the sidewalls 160. Crystal defects or dangling bonds as well as dislocations along the edges of the active layer 16 are prevented or significantly reduced due to the growth conditions and the selective area growth of the p-doped GaAlInP layer 16.

In particular, no etching of the edges of the respective active region 15 takes place. The passivation and encapsulation of the edges of the multi-quantum well structure and active layer 15 will block charge carriers from diffusing towards the semiconductor surface and recombining therein in a non-radiative manner.

The thickness along the side wall of layer 16 is adjusted by the respective growth conditions and satisfies the current spreading and passivation of the multi-quantum well structure. Usually, a few nanometres to about 200 nm are sufficient. Furthermore, the p-doped GaAlInP layer 16 extends along the sidewall of the multi-quantum well structure of active layer 15, as well as along the elevated sidewall portions of layer 13 all the way down to the top surface of hard mask layer 14, thereby fully encapsulating layer 13 and 15, respectively.

Following the next process step depicted in FIG. 1E), selective re-growth on the top surface of p-doped GaAlInP layer 16 is performed by depositing a p-doped contact layer 17 made of p-doped GaP or P-doped GaAs. As an alternative option in this regard, the p-contact layer 17 can also be isotropically overgrown on the side facets of p-doped GaAlInP layer 16. However, such overgrowth, which can be adjusted and controlled by respective growth conditions, provide the risk of leakage beside the active region, thereby reducing the performance of the optoelectronic device.

However, adjusting the growth conditions and the design accordingly provides the benefit of a simpler fabrication due to the avoidance of additional photoresist layers and their respective structuring thereof.

Following the next step illustrated in FIG. 1F), a full wafer deposition is conducted to apply conductive contact material 18 onto the layer stack. Said material is a conductive transparent material or a conductive metal and is deposited along the top surface of hard mask 14, the sidewalls of the p-doped layer 16, as well as on the top surface of layer 17. Material on the hard mask layer 14 forms areas 18′. Material is also deposited on the sidewalls 181, on top layer 18 thereby encapsulating the optoelectronic device.

The remaining steps follow a conventional Mesa structuring process, in which the photoresist layer 20 is deposited on top of layer 18 and structured accordingly to open recesses 22 surrounding the optoelectronic device. Then, those areas along the recesses 22 of the layer stack are etched resulting in a Mesa structure 21 as illustrated in FIG. 1H. The inclined sidewalls are a direct result of the structuring process and can be adjusted accordingly. After the etching process, a passivation layer 24, for example, comprising SiO₂ or Al₂O₃ is provided on the exposed sidewalls of the mesa structure 21.

Finally, the respective optoelectronic device is re-bonded and the previous growth surface 10 processed accordingly. The present example, illustrated in FIG. 1H) utilizes the growth substrate 10 as part of the optoelectronic device. This is possible as the growth substrate may be a conductive semiconductor, which as presented is covered by a thin metal layer to provide a carrier injection into the device. Other process steps like removing the growth substrate 10, buffer layer 11 as well as thinning the layer 12 and further measures can be applied based on the needs, requirements, and design choices.

As illustrated in the first embodiment according to FIGS. 1A) to 1H), the selective area growth process is enabled without additional structuring, etching or diffusion steps during the growth processes. Particularly, no additional etching is necessary for the active region, thereby avoiding contamination, dislocation, and further crystal defects along the edges of the active layer. The hard mask 14 is used as a self-aligned insulation layer, which might be important for tiny optoelectronic devices where the alignment is critical. Furthermore, the hard mask layer 14 can remain on the final optoelectronic device and is not removed later on.

The layer design is adjustable by varying the growth conditions of the various layer 13 and 16, which allows a suppression of desired current path particularly along the sidewalls of the optoelectronic device.

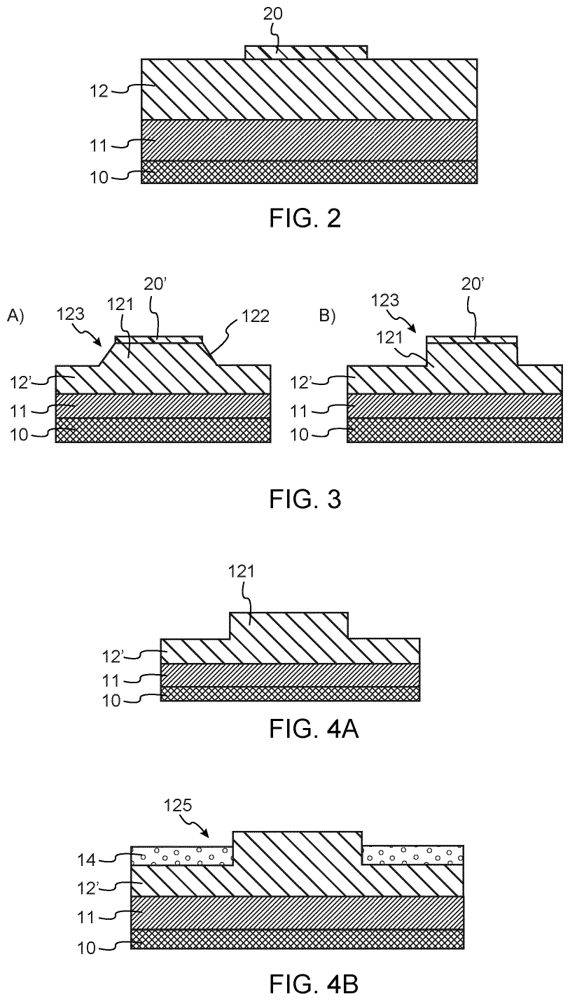

In the present example, the hard mask layer was deposited on top of layer 12 and subsequently structured to expose a respective growth surface in the 111 direction. FIGS. 2 and 3 illustrate a slightly different embodiment, leading to a protrusion area, which is subsequently used as a growth surface for the selective growth of additional layers.

In FIG. 2, a growth substrate 10 is provided and the p-doped buffer layer 11 applied thereupon. An undoped AlInP layer 12 is deposited on the top surface of layer 11. Then, a structured photoresist layer 20′ is deposited thereupon resulting in a portion of the surface of layer 12 covered. The area of the photoresist 20′ covering the surface portion of layer 12 comprises a rectangular shape when viewed from the top. The edges of that shape are oriented along the [111] direction of the crystal lattice on the top surface. This will ensure that subsequent etching process removes material along the edge portions, leaving the [111] surface substantially intact.

Following FIGS. 3A) and 3B), various etches can be applied to remove portions of layer material 12, resulting in a different structure when viewed from the top as well as from of the side.

FIG. 3A shows inclined surface 122 generated by the etching process leaving a protrusion 121 of the undoped AlInP layer 12 behind. The photoresist layer 20′ is covering its top surface. The inclination of the surface 122 is adjusted by the conditions for the etching process. The protrusion height is selected in such way that a top portion of the material of protrusion 121 still elevates the hard mask layer 14 deposited in a subsequent step.

In FIG. 3B), the etch is performed in such way that a substantially vertical edge of the protrusion 121 is achieved. Likewise, when viewed from the top, the shape of the protrusion 121 forms a hexagonal shape with recessed areas 123 surrounding it.

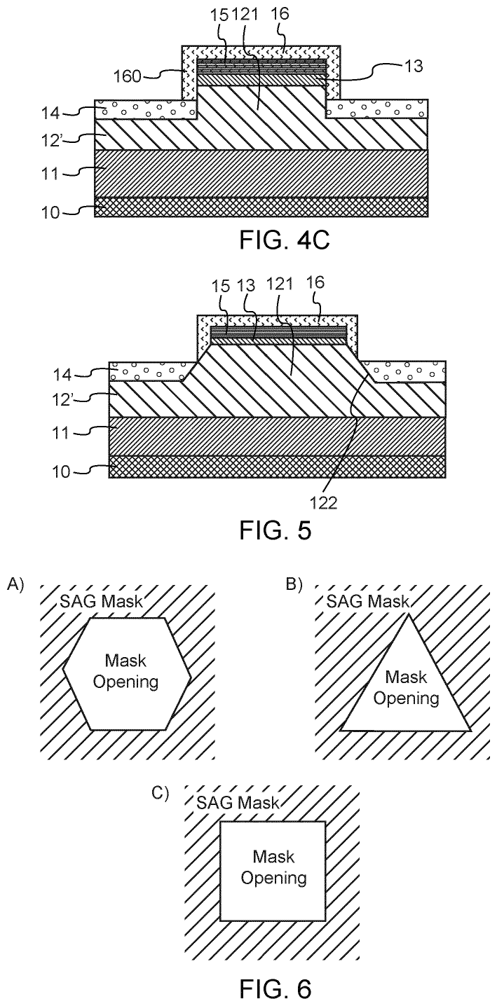

Continuing with FIG. 4A), the photoresist layer 20′ is removed from the top 111 surface of protrusion 121. A hard mask layer made of for example of the silicon dioxide, SiO₂ is applied to the exposed top surface of the layer stack. However, the top 111 surface of protrusion 121 is kept free from the hard mask material, either by proper protecting the top surface prior to deposition of the hard mask material, or simply removing the hard mask layer from the top surface in a subsequent etching step. The amorphous material of hard mask layer 14 surrounds of the protrusion still leaves an elevated portion of 125 behind.

Following FIG. 4B), the doped (GaₓAl₁₋ₓ)_{y}In_{1-y}P material of layer 13 is selectively re-grown on the top 111 surface of the protrusion 121. In this regard to the top surface acts as the exposed surface in the previous embodiment (see FIG. 1C). The growth process of the n-doped (GaₓAl₁₋ₓ)_{y}In_{1-y}P material 13 is selected such that no material overlaps the top surface. Consequently the growth condition may slightly vary from previous growth conditions, the temperature range between 650° C. to 850° areas and in particular between 700° C. and 730° C.

After depositing of the n-doped layer 13, the multi-quantum well structure 15 having various barrier and quantum well layers with different aluminum content are selectively re-grown. As explained previously, the subsequent step of depositing a p-doped layer 16 on the top surface of the multi-quantum well structure 15 and along the sidewalls of layer 13 and 121, respectively is achieved by a selective re-growth process. The material of layer 16 comprises a higher bandgap than the material of the active layer 15, thus causing an electric potential repelling charge carriers from diffusing to the edges of active layer 15. The material of layer 16 exceeds down to layer 14 which is similar as in the previous embodiment.

The resulting structure shown in FIG. 4C represents the layer stack of an optoelectronic device. Similar to the previous embodiment with the following process steps being repeated.

The alternative etching result of the layer 12 is illustrated in FIG. 3A) with its inclined surface 122 of the protrusion 121. The selective regrowth processes applied later on result in a slightly different structure depicted in FIG. 5.

The optoelectronic device comprises an inclined surface 122, which is partially covered by the hard mask layer 14 to about half of its height. On the top surface of protrusion 121, the (GaₓAl₁₋ₓ)_{y}In_{1-y}P layer 13 with parameter in the ranges already mentioned above is deposited with the active region 15 deposited thereupon. As the inclined surface 121 may actually facilitate an undesired growth, the growth conditions in this regard might be a slightly different compared to the growth conditions for processing an optoelectronic device according to FIG. 4C with vertical sidewalls.

However, the inclined surface does not extend along 111 direction supporting the usual selective growth. Consequently, by selecting and adjusting the growth conditions accordingly, the material of layer 13 or layer 15 is not deposited on the inclined surface.

After processing the active layer 15, the p-doped (GaₓAl₁₋ₓ)_{y}In_{1-y}P layer 16 with parameter x between 0.3 and 0.7 and more particular between 0.4 and 0.6. Parameter x can also be 0 which corresponds to InAlP, but may comprise values like 0.45, 0.5 and 0.55 or 0.6. Furthermore x may correspond to a varying concentration decreasing from a value like 0.7 or 0.5 to 0. Parameter y is between 0.3 and 0.7 and particularly between 0.4 and 0.6. The (GaₓAl₁₋ₓ)_{y}In_{1-y}P layer 16 is selectively regrown on the top surface and also on the side surface of the active layer 15, layer 13 as well as the exposed inclined surface is 122 of protrusion 121. Thereby, the conductive layer 16 completely encapsulates the protrusion and reaches down to the hard mask layer 14.

In the exemplary embodiment of FIG. 5, the material of layer 16 on the sidewalls does not cover the hard mask layer 14 but ends short before on the sidewalls of layer 12. However, such structure can be adjusted in accordance with the respective the growth conditions. Nevertheless, the thickness of sidewalls of layer 16 as well as the area covering the inclined surface is 122 should be kept significantly smaller than on the top surface to reduce the current injection directly from the material of p-doped layer 16 into the material of the n-doped protrusion layer 121. This can be achieved by proper selecting the growth conditions and probably the doping concentration such that the resistance value along the sidewalls significantly larger than on top of layer 16.

The previous etching process illustrated in FIG. 3A) provides a better control of the shape of the optoelectronic device and minimizes any negative effect of the selective area growth at the edge of the optoelectronic device. In particular, it has been observed that different Mesa shapes, like the inclined surface 122 as illustrated provides a simpler regrowth with a larger growth condition windows compared to the vertical sidewall illustrated in FIG. 3B).

FIG. 6 finally illustrates several potential shapes for the hard mask layer 14 in a top view. FIG. 6A) shows a mask opening forming a hexagonal shape, whereby the side edges of hard mask layer 14 follow mainly the [111] lateral surfaces. In FIG. 6B) a similar hard mask opening is illustrated with the edges of the hard mask oriented along the [111] B lateral surfaces, thereby forming a triangle. In both cases, the orientation of the hard mask edge along the [111] lateral surfaces support and promotes the selective growth of the subsequent layers, thereby reducing the dislocations and crystal defects. Any potential overlap, that is when the material during the selective growth exceeds the level of the top surface of a hard mask is negligible and does not result in an increase of dislocations.

In comparison, thereto a mask opening as shown in FIG. 6C) is for a substrate with a surface not optimal, as some of the edges of the hard mask are not aligned along the direction. This requires additional restrictions during the growth process to obtain a substantially defect free growth particularly along the edges of the hard mask. However, for a substrate having a [110] or a [100] surface a mask opening with a square shape as shown in FIG. 6C) is beneficial. The edges of the hard mask can thereby be oriented along the [100] or [110] lateral surfaces, thereby forming a square or rectangle.

The proposed method provides a significantly improvement of the performance of particularly small optoelectronic devices based on the GaAlInP material which is characterized by relatively large diffusion length. The regrowth process with a bandgap material larger than the bandgap of the respective active region causes an electrical field in the proximity of the active layer edges preventing charge carrier from reaching the surface of the active layer and non-radiative recombination centres.

The proposed principle requires less process steps and may therefore not only improve the overall performance of small optoelectronic devices but also reduce the costs for the manufacturing process.

1.-21. (canceled)

22. A method for processing an optoelectronic device, the method comprising:
providing a growth substrate having one of a [111], [110] or [100] surface with a (GaₓAl₁₋ₓ)_{y}In_{1-y}P buffer layer located on the growth substrate having a parameter x between 0.2 and 0.8, inclusive, and a parameter y between 0.3 and 0.7, inclusive;
re-growing a doped (GaₓAl₁₋ₓ)_{y}In_{1-y}P layer with a parameter x between 0.4 and 0.6, inclusive, and a parameter y between 0.3 and 0.7, inclusive, on exposed surfaces of an AlInP layer deposited on the buffer layer, the exposed surfaces surrounded by a structured hard mask comprising an amorphous material on non-exposed surfaces of the AlInP layer, wherein edges of the hard mask adjacent to at least one exposed portion of the of a surface of the AlInP layer extend along the [111] B lateral surfaces when the substrate has a [111] surface, or extend along the [110] lateral surfaces when the substrate has a surface, or extend along the [100] lateral surfaces when the substrate has a surface;
re-growing an active layer structure on the doped (GaₓAl₁₋ₓ)_{y}In_{1-y}P layer;
re-growing a doped or intrinsic (GaₓAl₁₋ₓ)_{y}In_{1-y}P layer along a top surface and sidewalls of the active layer down to the hard mask, wherein the (GaₓAl₁₋ₓ)_{y}In_{1-y}P layer comprises a bandgap that is larger than a bandgap of the active layer;
depositing an unstructured conductive material; and
mesa-structuring the optoelectronic device.

23. The method according to claim 22, wherein the edges of the hard mask adjacent to the at least one exposed portion of the surface of the AlInP layer extend along the [111] lateral surfaces when the substrate has a [111] surface.

24. The method according to claim 22, wherein the edges of the hard mask adjacent to the at least one exposed portion of the surface of the AlInP layer form, in top view, a triangle or a hexagonal structure with its side along a [111] lateral surface when the substrate has a [111] surface.

25. The method according to claim 22, wherein re-growing the doped (GaₓAl₁₋ₓ)_{y}In_{1-y}P layer comprises:
depositing the intrinsic AlInP layer on the buffer layer;
depositing the structured hard mask on the surface of the AlInP layer, the structured hard mask comprising a recess exposing the surface; and
depositing the doped (GaₓAl₁₋ₓ)_{y}In_{1-y}P layer on the exposed surface.

26. The method according to claim 22, wherein the re-growing a doped (GaₓAl₁₋ₓ)_{y}In_{1-y}P layer comprises:
depositing the structured hard mask on the buffer layer, the structured hard mask comprising a recess exposing a portion of the buffer layer surface;
depositing the intrinsic AlInP layer on the exposed portions of the buffer layer; and
depositing the doped (GaₓAl₁₋ₓ)_{y}In_{1-y}P layer on a top surface of the AlInP layer above the exposed portions.

27. The method according to claim 22, wherein re-growing the doped (GaₓAl₁₋ₓ)_{y}In_{1-y}P layer comprises:
depositing the intrinsic AlInP layer on the buffer layer;
applying a structured photoresist on the AlInP layer;
etching the AlInP layer to form a protrusion;
applying the amorphous material of the hard mask on top surface portions of the AlInP layer surrounding the protrusion; and
depositing the doped (GaₓAl₁₋ₓ)_{y}In_{1-y}P layer on the top surface of the protrusion.

28. The method according to claim 27, wherein etching the AlInP layer forms inclined sidewalls with an increasing area towards the buffer layer.

29. The method according to claim 22,
wherein a top surface of the deposited doped (GaₓAl₁₋ₓ)_{y}In_{1-y}P layer exceeds a top surface of the hard mask; and/or
wherein a top surface of the AlInP layer exceeds a top surface of the hard mask.

30. The method according to claim 22, further comprising providing a temperature, while depositing the doped (GaₓAl₁₋ₓ)_{y}In_{1-y}P, above 500° C.

31. The method according to claim 22, wherein the buffer layer is n-doped and the AlInP layer is n-doped or substantially intrinsic.

32. The method according to claim 22, wherein the amorphous material comprises at least one of SiO₂, SiN, or Al₂O₃.

33. The method according to claim 22, wherein re-growing the active layer structure comprises:
depositing a plurality of alternating layers of (GaₓAl₁₋ₓ)_{y}In_{1-y}P layers with different Al content forming a multi-quantum well structure; and
depositing a quantum well structure.

34. The method according to claim 22, wherein a portion of the re-grown doped (GaₓAl₁₋ₓ)_{y}In_{1-y}P layer exceeds partially on the top surface of the hard mask.

35. The method according to claim 22, wherein a thickness of the re-grown doped or intrinsic (GaₓAl₁₋ₓ)_{y}In_{1-y}P layer on the sidewalls of the active layer is in a range between 10 nm and 200 nm, inclusive.

36. The method according to claim 22, wherein t re-growing the doped or intrinsic (GaₓAl₁₋ₓ)_{y}In_{1-y}P layer comprises depositing a p-doped contact layer on the top surface of the re-grown doped or intrinsic (GaₓAl₁₋ₓ)_{y}In_{1-y}P layer.

37. The method according to claim 22, wherein the unstructured conductive material comprises one of ITO, Ag, Ti, TiN, or Au.

38. An optoelectronic device comprising:
a structured semiconductor layer stack arranged between a first contact area on a light emission surface and a second contact area on a surface opposite the light emission surface, the structured semiconductor layer stack comprising:
a hard mask layer including an amorphous material having a recess;
a doped (GaₓAl₁₋ₓ)_{y}In_{1-y}P layer with a parameter x between 0.4 and 0.6, inclusive, and a parameter y between 0.3 and 0.7, inclusive above or within the recess of the hard mask layer with its top surface elevated above a surface of the hard mask;
an active layer selectively arranged on the top surface of the (GaₓAl₁₋ₓ)_{y}In_{1-y}P layer, the active layer including a quantum well or multi-quantum well structure based on InGaAlP material with different Al contents between well layers and adjacent barrier layers of the quantum well or the multi-quantum well structure; and
a doped or intrinsic (GaₓAl₁₋ₓ)_{y}In_{1-y}P layer arranged on a top surface and sidewalls of the active layer tapering down to the hard mask layer.

39. The optoelectronic device according to claim 38,
wherein edges of the hard mask layer adjacent to the recess extend along the lateral surfaces, on which the hard mask layer is arranged; or
wherein edges of the hard mask adjacent to the at least one exposed portion of the surface of an underlying layer form, in top view, a triangle or a hexagonal structure with its side along a [111] lateral surface; or
wherein edges of the hard mask layer adjacent to the recess extend along the [110] lateral surfaces, on which the hard mask layer is arranged; or
wherein edges of the hard mask layer adjacent to the recess extend along the [100] lateral surfaces, on which the hard mask layer is arranged.

40. The optoelectronic device according to claim 38,
wherein the structured semiconductor layer stack further comprises an AlInP layer,
wherein the AlInP layer at least partially fills the recess, and/or
wherein the hard mask layer is arranged on the AlInP layer, and/or
wherein the AlInP layer comprises at least partially inclined sidewalls adjacent to the amorphous material of the hard mask layer.

41. The optoelectronic device according to claim 38, further comprising an unstructured conductive material arranged on the doped or intrinsic (GaₓAl₁₋ₓ)_{y}In_{1-y}P layer and a surrounding material of the hard mask layer.

42. The optoelectronic device according to claim 41, wherein the hard mask layer comprises SiO₂, SiN, or Al₂O₃, and wherein the unstructured conductive material comprises ITO, Ag, Ti, TiN, or Au.
